(19) United States
(12) Patent Application Publication
(10) Pub. No.: US 2026/0128065 A1
(43) Pub. Date: May 7, 2026

(54) VERTICAL TWIST BITLINES WITH FOLDED BITLINE SENSE AMPLIFIER

(71) Applicant: Samsung Electronics Co., Ltd., Suwon-si (KR)

(72) Inventors: Jongsik NA, Dublin, CA (US); Anthony KANAGO, Fremont, CA (US); Sangmin HWANG, San Jose, CA (US)

(21) Appl. No.: 19/246,674

(22) Filed: Jun. 23, 2025

Related U.S. Application Data
(60) Provisional application No. 63/725,539, filed on Nov. 26, 2024.

(51) Int. Cl. G11C 5/06; G11C 11/4091

(52) U.S. Cl. CPC G11C 5/063; G11C 11/4091

(57) ABSTRACT

Provided are systems, methods, and apparatuses for vertical twist bitlines based on a folded bitline sense amplifier. The systems, devices, and methods include routing, at a first location, a first metal line from a first routing layer to a second routing layer, and a second metal line from the second routing layer to the first routing layer; connecting, within a first span starting at the first location, the second metal line to at least a first pair of vertical bitlines; routing, at a second location, the first metal line from the second routing layer to the first routing layer, and the second metal line from the first routing layer to the second routing layer; and connecting, within a second span starting at the second location, the first metal line to at least a second pair of vertical bitlines.

### CROSS-REFERENCE TO RELATED APPLICATIONS

This application claims the benefit of U.S. Provisional Patent Application Ser. No. 63/725,539, filed Nov. 26, 2024, which is incorporated by reference herein for all purposes.

### TECHNICAL FIELD

The disclosure relates generally to memory systems. In particular, the subject matter relates to vertical twist bitlines based on a folded bitline sense amplifier.

### SUMMARY

Memory chips can include integrated circuits that store and retrieve data in digital devices, such as computers, mobile devices, etc. Memory chips can store data temporarily or permanently. Memory chips can include random-access memory (RAM), dynamic random-access memory (DRAM), read-only memory (ROM), flash memory, etc. Memory chips can include output lines that connect to a system data bus. A decoder can select a single memory chip for the microprocessor to access. Some memory chips may be cut from a wafer and placed in individual housings. Memory chips can be mounted to a printed circuit board (PCB), incorporated on a system on chip (SoC), stacked vertically, etc.

The systems and methods described herein may be based on and/or may include stacked memory modules (e.g., 3D DRAM, vertically stacked (VS) DRAM). Stacked memory may use 3D stacking technology to increase the memory cell density of memory chips. The stacked memory modules can provide higher bandwidth, faster data transfer, and lower power consumption, which can help extend battery life for some devices (e.g., mobile devices).

The systems and methods described herein may be based on and/or may include a bitline (BL), local bitline (LBL), and/or BL sense amplifier (SA). A given BLSA may connect to a BL of a memory chip and may detect and/or amplify relatively small voltage changes on the BL to accurately read the data stored in that memory cell (e.g., binary 0 or 1). The systems and methods described herein may be based on and/or may include a word line (WL). A voltage signal applied to a given WL may enable corresponding memory cells in that row to interact with bitlines, allowing data to be read from or written to that particular row. Thus, the WL may act as a control line to activate a specific set of memory cells within a memory array.

In various embodiments, the systems and methods described herein include systems, methods, and apparatuses for vertical twist bitlines based on a folded bitline sense amplifier. In some embodiments, the described method comprises routing, at a first location, a first metal line from a first routing layer to a second routing layer and a second metal line in the reverse direction within a stacked memory module. The method further includes connecting, within a first span beginning at that location, the second metal line to at least a first pair of vertical bitlines; then routing, at a second location, the metal lines in reversed directions; and connecting, within a second span beginning at that second location, the first metal line to at least a second pair of vertical bitlines. In some embodiments, the method further includes establishing connections to a sense amplifier through a first via from the first metal line within the first or a subsequent span and a second via from the second metal line within the second or a subsequent span. Additional embodiments include configuring a wordline to share a charge with the second via when activated while ensuring isolation of the first via from such charge, orienting the wordline orthogonally to both the vertical bitlines and the metal lines, grouping multiple banks of vertical bitlines wherein one bank incorporates the metal lines, vias, and the sense amplifier, and routing sets of wordlines adjacent to the vertical bitlines to connect to corresponding sets of memory cells. In some embodiments, the first and second metal lines connect to M and N vertical bitlines respectively, with M and N being positive integers that are multiples of two (e.g., 2, 4, 6, 8, 10, 12, 14, 16, etc.).

In other embodiments, the described technology provides a stacked memory module including a first metal line and a second metal line that are routed between a first routing layer and a second routing layer. At a first location, the second metal line is connected within a first span to a first pair of vertical bitlines, while at a second location the first metal line is connected within a second span to a second pair of vertical bitlines. In some embodiments, the module further comprises a sense amplifier that is connected via a first via from the first metal line and a second via from the second metal line, with the vias being routed within the respective spans or subsequent spans. The module may be configured to read stored values by activating a wordline so that a voltage differential between the vias is detected, and in alternative embodiments the wordline is designed to share a charge with one via while isolating the other, with the wordline oriented orthogonal to both the metal lines and the vertical bitlines. Furthermore, the module can include multiple banks of vertical bitlines, where at least one bank incorporates the metal lines, vias, wordline, and sense amplifier, and wordlines are routed adjacent to respective vertical bitlines to connect with memory cells.

In some embodiments, the described fabrication system includes a routing controller configured to route a first metal line and a second metal line between routing layers of a stacked memory module. The routing controller directs routing at a first location so that the first metal line and the second metal line traverse from one routing layer to the other, facilitating a connection of the second metal line within a first span to a first pair of vertical bitlines. The routing controller further directs routing at a second location so that the metal lines reverse direction, with the first metal line being connected within a second span to a second pair of vertical bitlines. In some embodiments, the fabrication system also establishes connections from the metal lines to a sense amplifier through first and second vias, routed within the respective spans or in subsequent spans, and configures a wordline so that the wordline shares a charge with the second via upon activation while isolating the first via from such charge. These and other features of the described system provide enhanced flexibility in the routing and interconnection of components in stacked memory modules.

The systems and methods described herein include multiple advantages and benefits. For example, the systems and methods described herein may reduce or minimize (e.g., cancel) coupling between LBLs (e.g., vertical local bitline). The systems and methods described herein may avoid or minimize (e.g., cancel) coupling between BLs (e.g., same crosstalk to BL and BLB with folded bitline sense amplifier). The systems and methods described herein may provide a higher delta bitline voltage (VBL) between BL/BLB during charge sharing, enabling the sense amplifier to more easily sense the correct voltage level of a given memory cell.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings, wherein:

FIG. 1 illustrates an example system in accordance with one or more implementations as described herein.

FIG. 2 illustrates an example system in accordance with one or more implementations as described herein.

FIG. 3 illustrates an example system in accordance with one or more implementations as described herein.

FIG. 4 illustrates an example system in accordance with one or more implementations as described herein.

FIG. 5 illustrates an example system in accordance with one or more implementations as described herein.

FIG. 6 depicts a flow diagram illustrating an example method associated with the disclosed systems, in accordance with example implementations described herein.

FIG. 7 depicts a flow diagram illustrating an example method associated with the disclosed systems, in accordance with example implementations described herein.

FIG. 8 illustrates an example system in accordance with one or more implementations as described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media includes all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), erasable programmable read-only memory (EPROM), electrically erasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random-access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of a hardware embodiment, a computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, a hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some example embodiments, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on chip (SoC), an assembly, and so forth.

The provided description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

It is noted that, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Data processing may include data buffering, aligning incoming data from multiple communication lanes, forward error correction (FEC), etc. For example, data may be received by an analog front end (AFE), which can prepare the incoming data for digital processing. The digital portion of the transceivers (e.g., digital signal processor (DSP)) may provide skew management, equalization, reflection cancellation, and/or other functions. It is to be appreciated that the process described herein can provide many benefits, including saving both power and cost.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, SoC, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

As would be apparent to one skilled in the art, various functions of circuit elements may also be implemented as processing blocks in a software program. Such software may be employed in, for example, a digital signal processor, microcontroller, or general-purpose computer. Such software may be embodied in the form of program code embodied in tangible media, such as magnetic recording media, optical recording media, solid-state memory, floppy diskettes, CD-ROMs, hard drives, or any other non-transitory machine-readable storage medium, that when the program code is loaded into and executed by a machine, such as a computer, the machine becomes an apparatus for practicing the subject matter disclosed herein. When implemented on a general-purpose processor, the program code segments combine with the processor to provide a unique device that operates analogously to specific logic circuits. Described embodiments may also be manifest in the form of a bit stream or other sequence of signal values electrically or optically transmitted through a medium, stored magnetic-field variations in a magnetic recording medium, etc., generated using a method and/or an apparatus as described herein.

In the context of memory circuits, bitline (BL) and bitline bar (BLB) may represent a pair of bitlines, one complementary to the other. BL and BLB may be used to store and read data within memory cells. In some cases, BL may carry the data or signal associated with a given memory cell and BLB may be the complement of BL (e.g., provide a reference voltage to BL). In other cases, BLB may carry the data or signal associated with a given memory cell and BL may be the complement of BLB (e.g., provide a reference voltage to BLB).

In 3D memory structures, bitlines can be arranged vertically, creating a higher density of memory elements, making a given memory cell closer to adjacent memory cells. 3D memory structures with vertical bitlines can have increased coupling issues due to the proximity of memory elements. The coupling can occur based on capacitive and/or inductive effects between the vertical local bitlines. Such coupling can result in signal leakage and/or interference between neighboring bitlines. The signal leakage and/or interference can lead to data corruption or errors, especially in high-density memory structures like 3D memories. With 2D or planar memory structures, bitline capacitance may be driven by coupling to the cell device and capacitor, which can act as a shield between adjacent bitlines. With 3D memory structures, the capacitance of a memory cell may be coupled to adjacent wiring, which can lead to data corruption or errors. For example, based on charge sharing, coupling between bitlines may affect both reference bitline and charge shared bitlines.

In some cases, a sense amplifier may sense the value of a memory cell based on a differential voltage between BL and BLB (e.g., delta VBL). Coupling between bitlines, wordlines, memory cells, etc., can reduce delta VBL, reducing the ability of the sense amplifier to sense the charge of a memory cell. The systems and methods described herein may include a bitline scheme that provides a folded bitline sense amplifier (BLSA). Based on the systems and methods described herein, delta VBL may be the same as cases without coupling (e.g., canceled coupling). Based on the systems and methods described herein, a coupling effect may result in half of an open bitline coupling to charge a shared bitline, and half of the open bitline coupling to a reference bitline. Some systems may use dummy mats to minimize coupling, which may include a placeholder or an inactive area of the semiconductor material that is intentionally designed to surround the active memory cell, helping to isolate the active memory cell electrically and prevent unwanted interference from neighboring cells. The systems and methods described herein may avoid or minimize the use of dummy mats.

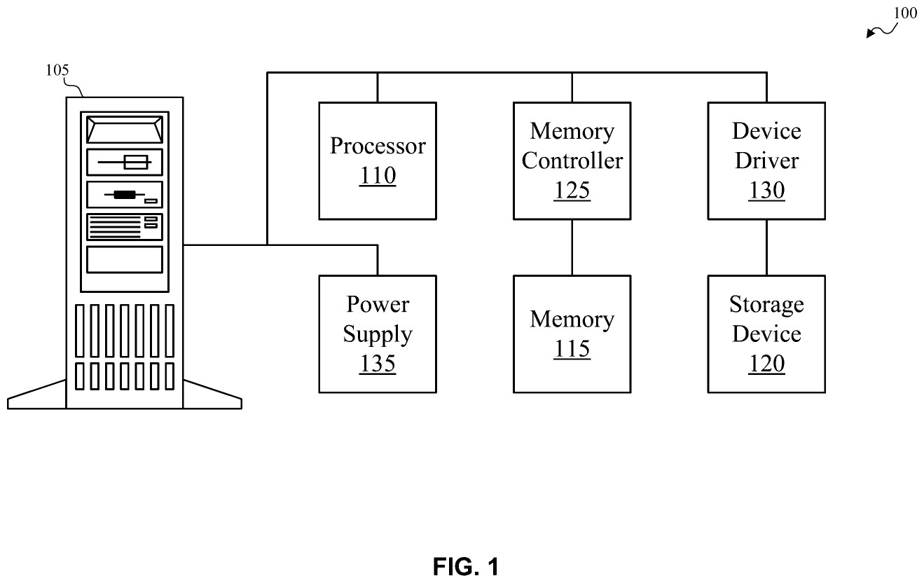

FIG. 1 illustrates an example system 100 in accordance with one or more implementations as described herein. In FIG. 1, machine 105, which may be termed a host, a system, or a server, is shown. While FIG. 1 depicts machine 105 as a tower computer, embodiments of the disclosure may extend to any form factor or type of machine. For example, machine 105 may be a rack server, a blade server, a desktop computer, a tower computer, a mini tower computer, a desktop server, a laptop computer, a notebook computer, a tablet computer, etc.

Machine 105 may include processor 110, memory 115, and storage device 120. Processor 110 may be any variety of processor. It is noted that processor 110, along with the other components discussed below, are shown outside the machine for ease of illustration: embodiments of the disclosure may include these components within the machine. While FIG. 1 shows a single processor 110, machine 105 may include any number of processors, each of which may be single core or multi-core processors, each of which may implement a Reduced Instruction Set Computer (RISC) architecture or a Complex Instruction Set Computer (CISC) architecture (among other possibilities), and may be mixed in any desired combination.

Processor 110 may be coupled to memory 115. Memory 115 may be any variety of memory, such as flash memory, DRAM, SRAM, Persistent Random Access Memory, Ferroelectric Random Access Memory (FRAM), or Non-Volatile Random Access Memory (NVRAM), such as Magnetoresistive Random Access Memory (MRAM), Phase Change Memory (PCM), or Resistive Random-Access Memory (ReRAM). In some cases, at least a portion of memory 115 may include stacked memory (e.g., 3D DRAM, VS-DRAM). Memory 115 may include volatile and/or non-volatile memory. Memory 115 may use any desired form factor: for example, Single In-Line Memory Module (SIMM), Dual In-Line Memory Module (DIMM), Non-Volatile DIMM (NVDIMM), etc. Memory 115 may be any desired combination of different memory types, and may be managed by memory controller 125. Memory 115 may be used to store data that may be termed “short-term”: that is, data not expected to be stored for extended periods of time. Examples of short-term data may include temporary files, data being used locally by applications (which may have been copied from other storage locations), and the like.

Processor 110 and memory 115 may support an operating system under which various applications may be running. These applications may issue requests (which may be termed commands) to read data from or write data to either memory 115 or storage device 120. When storage device 120 is used to support applications reading or writing data via some sort of file system, storage device 120 may be accessed using device driver 130. While FIG. 1 shows one storage device 120, there may be any number (one or more) of storage devices in machine 105. Storage device 120 may support any desired protocol or protocols, including, for example, the Non-Volatile Memory Express (NVMe®) protocol, a Serial Attached Small Computer System Interface (SCSI) (SAS) protocol, or a Serial AT Attachment (SATA) protocol. Storage device 120 may include any desired interface, including, for example, a Peripheral Component Interconnect Express (PCIe®) interface, or a Compute Express Link (CXL®) interface. Storage device 120 may take any desired form factor, including, for example, a U.2 form factor, a U.3 form factor, a M.2 form factor, Enterprise and Data Center Standard Form Factor (EDSFF) (including all of its varieties, such as E1 short, E1 long, and the E3 varieties), or an Add-In Card (AIC).

While FIG. 1 uses the term “storage device,” embodiments of the disclosure may include any storage device formats that may benefit from the use of computational storage units, examples of which may include hard disk drives, solid state drives (SSDs), or persistent memory devices, such as PCM, ReRAM, or MRAM. Any reference to “storage device” “SSD” herein should be understood to include such other embodiments of the disclosure and other varieties of storage devices. In some cases, the term “storage unit” may encompass storage device 120 and memory 115. Machine 105 may include power supply 135. Power supply 135 may provide power to machine 105 and its components.

In one or more examples, machine 105 may be implemented with any type of apparatus. Machine 105 may be configured as (e.g., as a host of) one or more servers, such as a computation server, a storage server, storage node, a network server, a supercomputer, data center system, and/or the like, or any combination thereof. Additionally, or alternatively, machine 105 may be configured as (e.g., as a host of) one or more computers, such as a workstation, a personal computer, a tablet, a smartphone, and/or the like, or any combination thereof. Machine 105 may be implemented with any type of apparatus that may be configured as a device including, for example, an accelerator device, a storage device, a network device, a memory expansion and/or buffer device, a central processing unit (CPU), a graphics processing unit (GPU), a neural processing unit (NPU), a tensor processing unit (TPU), optical processing units (OPU), and/or the like, or any combination thereof.

Any communication between devices including machine 105 (e.g., host, computational storage device, and/or any intermediary device) can occur over an interface that may be implemented with any type of wired and/or wireless communication medium, interface, protocol, and/or the like including PCIe, NVMe, Ethernet, NVMe-oF, Compute Express Link (CXL), and/or a coherent protocol such as CXL.mem, CXL.cache, CXL.IO and/or the like, Gen-Z, Open Coherent Accelerator Processor Interface (OpenCAPI), Cache Coherent Interconnect for Accelerators (CCIX), Advanced extensible Interface (AXI) and/or the like, or any combination thereof, Transmission Control Protocol/Internet Protocol (TCP/IP), FibreChannel, InfiniBand, Serial AT Attachment (SATA), Small Computer Systems Interface (SCSI), Serial Attached SCSI (SAS), iWARP, any generation of wireless network including 2G, 3G, 4G, 5G, and/or the like, any generation of Wi-Fi, Bluetooth, near-field communication (NFC), and/or the like, or any combination thereof. In some embodiments, the communication interfaces may include a communication fabric including one or more links, buses, switches, hubs, nodes, routers, translators, repeaters, and/or the like. In some embodiments, system 100 may include one or more additional apparatus having one or more additional communication interfaces.

Any of the functionality described herein, including any of the host functionality, device functionally, and/or the like, may be implemented with hardware, software, firmware, or any combination thereof including, for example, hardware and/or software combinational logic, sequential logic, timers, counters, registers, state machines, volatile memories such as at least one of or any combination of the following: DRAM and/or SRAM, nonvolatile memory including flash memory, persistent memory such as cross-gridded nonvolatile memory, memory with bulk resistance change, PCM, and/or the like and/or any combination thereof, complex programmable logic devices (CPLDs), field programmable gate arrays (FPGAs), application specific integrated circuits (ASICs), CPUs including CISC processors such as x86 processors and/or RISC processors such as RISC-V and/or advanced RISC machine (ARM) processors, GPUs, NPUs, TPUs, OPUs, and/or the like, executing instructions stored in any type of memory.

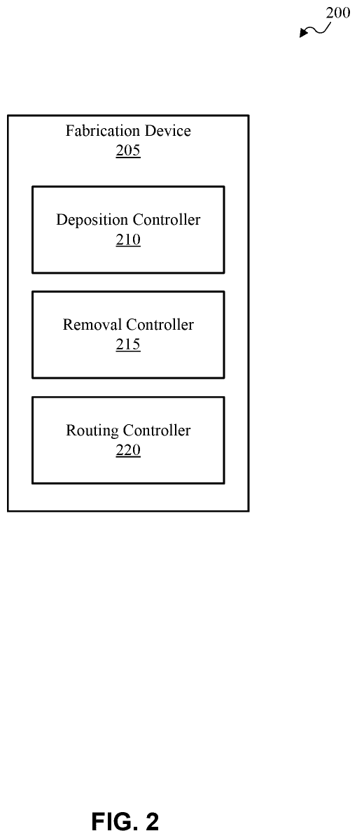

FIG. 2 illustrates an example system 200 in accordance with one or more implementations as described herein. As shown, system 200 may include fabrication device 205. Fabrication device 205 may include any one or combination of logic (e.g., logical circuit), hardware (e.g., processing unit, memory, storage), software, firmware, and the like, that enable fabrication device 205 to provide the systems and methods described herein of selective metal deposition for memory cell transistors.

In the illustrated example, fabrication device 205 may include deposition controller 210, removal controller 215, and routing controller 220. In some cases, deposition controller 210 and/or removal controller 215 may include any one or combination of logic (e.g., logical circuit), hardware (e.g., processing unit, memory, storage), software, firmware, and the like. One or more aspects of vertical twist bitlines and/or a folded bitline sense amplifier described herein may be fabricated in conjunction with system 200 (e.g., components of system 200).

Deposition controller 210 may include a control system that manages the parameters of a deposition process, where a thin layer of material is deposited onto a wafer to create the electronic components within an integrated circuit (IC). Deposition controller 210 may regulate factors like temperature, gas flow, pressure, and plasma conditions to ensure the deposited film has the desired properties and thickness for optimal device performance. Deposition controller 210 may provide chemical vapor deposition (CVD) where precursor gases react on the wafer surface to form a solid film; plasma enhanced CVD (PECVD) where plasma is used to enhance chemical reactions, enabling deposition at lower temperatures; and/or atomic layer deposition (ALD), where a single layer of atoms may be deposited at a time.

Removal controller 215 may control the process of removing material from a wafer during etching, which may include dry etching and/or plasma etching, ensuring that only the desired areas are removed with the correct depth and precision to create the desired circuit features on a given chip. Removal controller 215 may manage the rate and selectivity of material removal during the etching step.

Routing controller 220 may control the process of laying out metal traces, metal lines (e.g., copper lines), vias (e.g., through-silicon vias) that provide electrical pathways for signals and power flow between different components and layers of a device (e.g., 3D DRAM).

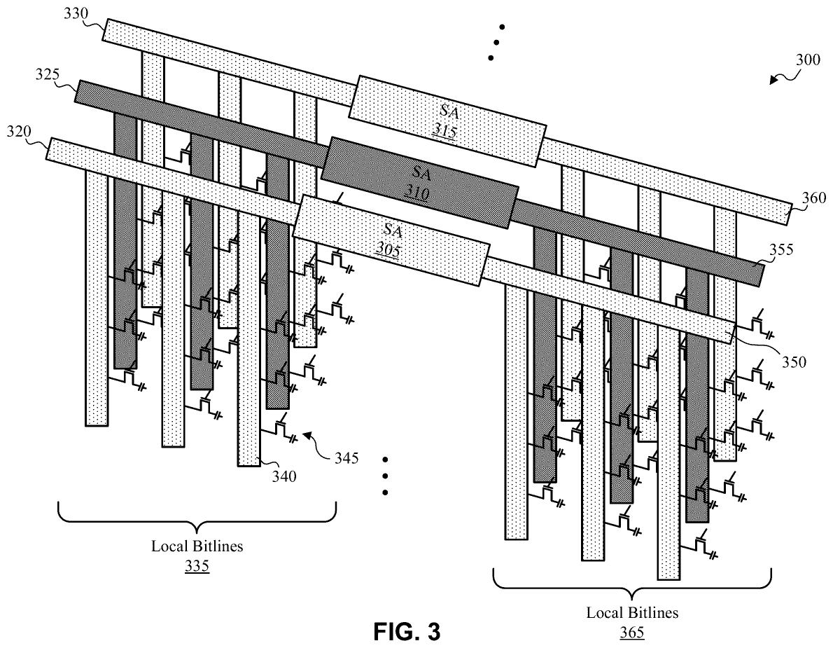

FIG. 3 illustrates an example system 300 in accordance with one or more implementations as described herein. In some cases, one or more aspects of system 300 may be fabricated by or in conjunction with system 200 of FIG. 2. In some configurations, one or more aspects of system 300 may be implemented by or in conjunction with machine 105, components of machine 105, or any combination thereof.

In the illustrated example, system 300 may include a first bank with sense amplifier (SA) 305, a second bank with SA 310, a third bank with SA 315, and so on. As shown, the first bank may include global bitline 320 connected to SA 305 and global bitline 350 connected to SA 305. The second bank may include global bitline 325 and global bitline 355 connected to SA 310. The third bank may include global bitline 330 and global bitline 360 connected to SA 315.

As shown, local bitlines 335 may connect, respectively, to global bitline 320, global bitline 325, and global bitline 330. Similarly, local bitlines 365 may connect, respectively, to global bitline 350, global bitline 355, and global bitline 360. It is noted that an SA of a given bank may be connected to one or more memory cell arrays. For example, the local bitlines and memory cells connected to global bitline 320 may be a first memory cell array connected to SA 305. As shown, the local bitlines and memory cells connected to global bitline 350 may be part of a second memory cell array connected to SA 305. Thus, SA 305 may be part of a first bank that includes a first set of one or more memory cell arrays connected to SA 305; SA 310 may be part of a second bank that includes a second set of one or more memory cell arrays connected to SA 310; and SA 315 may be part of a third bank that includes a third set of one or more memory cell arrays connected to SA 315.

In some examples, the depicted components of system 300 may be formed in a stacked memory module, where the depicted local bitlines (e.g., local bitlines 335, local bitlines 365) may be formed vertically (e.g., orthogonal to the global bitlines). In some cases, wordlines may run between local bitlines 335 and local bitlines 365, where the wordlines may be orthogonal to local bitlines 335, local bitlines 365, and global bitlines 320-360. For example, local bitlines 335 and local bitlines 365 may be considered running in the direction of a Z-axis (e.g., vertically), global bitlines 320-360 in the direction of an X-axis, and the wordlines in the direction of a Y-axis.

As shown, a given local bitline may connect to multiple memory cells. For example, local bitline 340 of local bitlines 335 may connect to global bitline 320 and to at least one memory cell (e.g., memory cell 345), where a given memory cell may include a transistor to control access to the memory cell and a capacitor to hold an electrical charge indicating a value of the memory cell.

Based on the proximity of the components of system 300, charges on bitlines (e.g., local bitlines, global bitlines), memory cells, and/or wordlines of the first bank may affect the charges on bitlines, memory cells, and/or wordlines of the second bank, and so on. For example, charge coupling may occur between the depicted first bank and the second bank, between the depicted second bank and third bank, etc. The charge coupling can result in memory read errors, memory write errors, data destruction, etc.

The systems and methods described herein may include bitline mechanisms based on a folded bitline sense amplifier (BLSA). For example, the systems and methods described herein may be based on twisting global bitlines (e.g., global bitlines 320-360) and configuring an SA (e.g., SA 305, SA 310, SA 315) to detect and amplify a voltage differential (e.g., delta VBL) between a pair of bitlines (e.g., between a charged global bitline and a reference global bitline). Accordingly, the systems and methods described herein may reduce or minimize (e.g., cancel) coupling between vertical bitlines (e.g., local bitlines 335, local bitlines 365)). Based on reducing coupling between local bitlines, the systems and methods described herein may provide a higher delta VBL of BL/BLB during charge sharing, enabling a given sense amplifier (e.g., SA 305, SA 310, SA 315) to more easily sense the correct voltage level of a given memory cell.

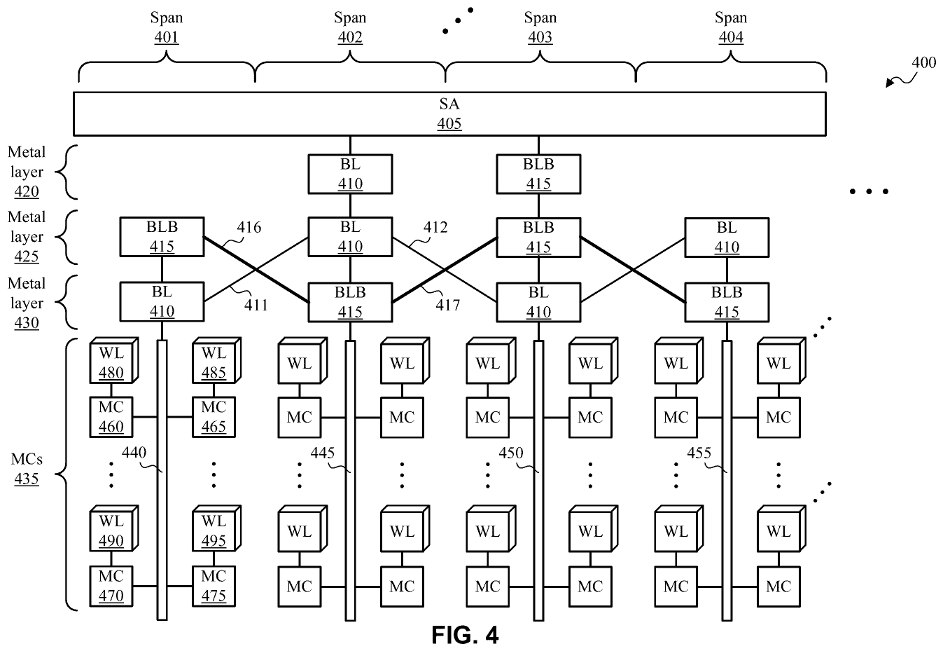

FIG. 4 illustrates an example system 400 in accordance with one or more implementations as described herein. In some cases, one or more aspects of system 300 may be fabricated by or in conjunction with system 200 of FIG. 2. In some configurations, one or more aspects of system 400 may be implemented by or in conjunction with machine 105, components of machine 105, or any combination thereof. FIG. 4 may depict a cross-section view of vertical twist global bitlines.

In the illustrated example, system 400 may include SA 405, bitline (BL) 410, and bitline bar (BLB) 415. In some cases, BL 410 may be referred to as a global bitline that connects to a first set of one or more local bitlines. Similarly, BLB 415 may be referred to as a global bitline bar that connects to a second set of one or more local bitlines. As shown, system 400 may include multiple memory cells 435 (e.g., memory cells 435 of the bank of SA 405) that connect to respective local bitlines of system 400.

In some configurations, SA 405 may be located above the depicted components of system 400 (e.g., above BL 410, BLB 415, memory cells 435, etc.). In some cases, system 400 may depict one bank of multiple banks. For example, system 400 may include multiple banks that include the bank of SA 405. In some cases, the multiple banks may continue into and/or from the page when viewing FIG. 4, where the components of system 400 are duplicated in a second bank, duplicated in a third bank, etc.

As shown, system 400 may include metal layer 420 under SA 405, metal layer 425 under metal layer 420, and metal layer 430 under metal layer 425. In some configurations, BL 410 may be routed from metal layer 425 to metal layer 430, and from metal layer 430 to metal layer 425. Similarly, BLB 415 may be routed from metal layer 425 to metal layer 430, and from metal layer 430 to metal layer 425. In the illustrated example, BLB 415 may be routed, via metal line 416, from metal layer 425 to metal layer 430. And BLB 415 may be routed, via metal line 417, from metal layer 430 to metal layer 425. In the illustrated example, BL 410 may be routed, via metal line 411, from metal layer 430 to metal layer 425. And BL 410 may be routed, via metal line 412, from metal layer 425 to metal layer 430.

Within a first span (e.g., span 401), BL 410 may be routed through metal layer 430, and BLB 415 may be routed over BL 410, through metal layer 425. Within span 401, BL 410 may connect to local bitline (LBL) 440. As shown, LBL 440 may be positioned vertically under metal layer 430. In some cases, LBL 440 may connect to a first portion of memory cells 435 of system 400. For example, LBL 440 may connect to memory cell 460, memory cell 465, memory cell 470, and memory cell 475. As shown, the first portion of memory cells 435 may connect to a first portion of wordlines that run through system 400 on either side of LBL 440. For example, a first set of wordlines may run adjacent to and on a first side of LBL 440 and a second set of wordlines may run adjacent to and on a second side of LBL 440. As shown, memory cell 460 may connect to wordline (WL) 480, memory cell 465 may connect to WL 485, memory cell 470 may connect to WL 490, and memory cell 475 may connect to WL 495.

In some examples, to read memory cell 460, WL 480 may be activated (e.g., an active charge applied to WL 480). The voltage level of BL 410, connected to memory cell 460 and SA 405, may be affected based on activating WL 480. SA 405 may compare a voltage level of BL 410 to a voltage level of BLB 415, where the voltage level of BLB 415 may be a reference voltage for BL 410. SA 405 may detect a slight voltage difference (e.g., delta VBL) between BL 410 and BLB 415, which may indicate the value stored at memory cell 460.

Between span 401 and a second span (e.g., span 402), BL 410 may be routed from metal layer 430 to metal layer 425, while BLB 415 may be routed from metal layer 425 to metal layer 430. Within span 402, BLB 415 may be routed through metal layer 430, and BL 410 may be routed over BLB 415, through metal layer 430. Within span 402, BLB 415 may connect to LBL 445. As shown, LBL 445 may be positioned vertically under metal layer 430. In some cases, LBL 445 may connect to a second portion of memory cells 435 of system 400. As shown, the second portion of memory cells 435 may connect to a second portion of wordlines that run through system 400 on either side of LBL 445. For example, a first set of wordlines may run adjacent to and on a first side of LBL 445 and a second set of wordlines may run adjacent to and on a second side of LBL 445.

Between span 402 and a third span (e.g., span 403), BL 410 may be routed from metal layer 425 to metal layer 430, while BLB 415 may be routed from metal layer 430 to metal layer 425. Within span 403, BL 410 may be routed through metal layer 430, and BLB 415 may be routed over BL 410, through metal layer 425. Within span 403, BL 410 may connect to LBL 450. As shown, LBL 450 may be positioned vertically under metal layer 430. In some cases, LBL 450 may connect to a third portion of memory cells 435 of system 400. As shown, the third portion of memory cells 435 may connect to a third portion of wordlines that run through system 400 on either side of LBL 450. For example, a first set of wordlines may run adjacent to and on a first side of LBL 450 and a second set of wordlines may run adjacent to and on a second side of LBL 450.

Between span 403 and a fourth span (e.g., span 404), BL 410 may be routed from metal layer 430 to metal layer 425, while BLB 415 may be routed from metal layer 425 to metal layer 430. Within span 404, BL 410 may be routed through metal layer 430, and BLB 415 may be routed over BL 410, through metal layer 425. Within span 404, BL 410 may connect to LBL 455. As shown, LBL 455 may be positioned vertically under metal layer 430. In some cases, LBL 455 may connect to a fourth portion of memory cells 435 of system 400. As shown, the fourth portion of memory cells 435 may connect to a fourth portion of wordlines that run through system 400 on either side of LBL 455. For example, a first set of wordlines may run adjacent to and on a first side of LBL 455 and a second set of wordlines may run adjacent to and on a second side of LBL 455.

As shown, system 400 may include multiple WLs that include WLs 480-495. In some examples, the multiple WLs may run into and/or out from the page when viewing FIG. 4. For example, the multiple WLs may connect to other banks of memory cells that connect to other vertical local bitlines, which connect to other SAs. For example, in addition to connecting to memory cell 460, WL 480 may connect to a second memory cell of a second bank adjacent to the bank of SA 405. Additionally, WL 480 may connect to a third memory cell of a third bank adjacent to the second bank, and so on.

As shown, SA 405 may connect to at least one pair of bitlines (e.g., BL 410 and BLB 415). In some cases, SA 405 may connect to two or more pairs of bitlines. For example, SA 405 may connect to a first bitline pair (e.g., BL 410 and BLB 415) as well as at least one additional bitline pair (e.g., a second BL and BLB pair). In some cases, the second pair of bitlines may include another BL connection to SA 405 and another BLB connection to SA 405. The second BL connection may connect to a first twisted bitline similar to BL 410, and the second BLB connection may connect to a second twisted bitline similar to BLB 415. The second BL may connect to a first set of one or more local bitlines similar to LBL 440 and LBL 450, and the second BLB may connect to a second set of one or more local bitlines similar to LBL 445 and LBL 455. The second BL may be electrically isolated (e.g., not connected) to BL 410 or BLB 415. Similarly, the second BLB may be electrically isolated (e.g., not connected) to BL 410 or BLB 415. In some cases, the depicted components of system 400 may be referred to as a first array (e.g., first memory cell array), and the components of the second BL and second BLB may be referred to as a second array (e.g., second memory cell array). Thus, one or more memory cell arrays may connect to SA 405.

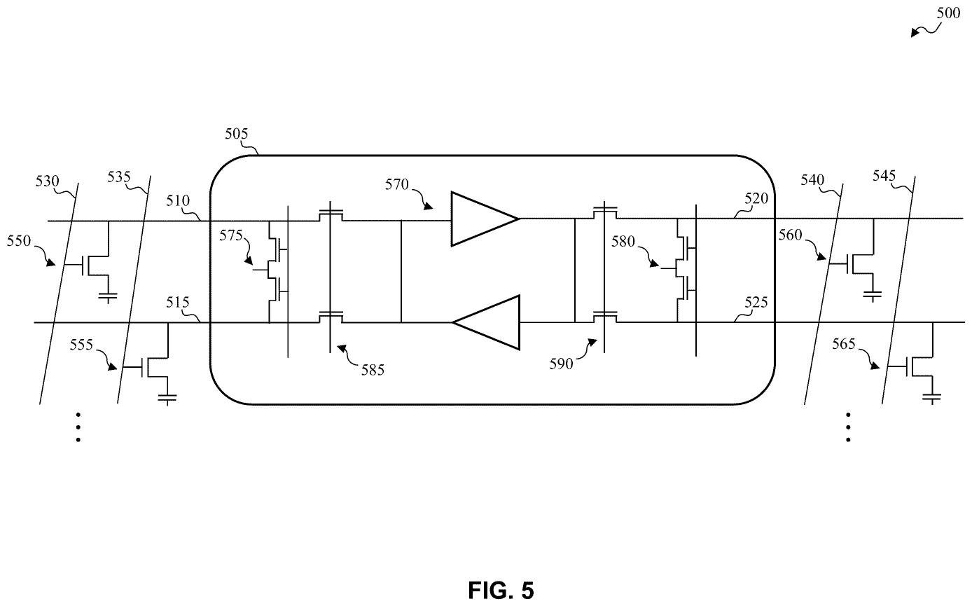

FIG. 5 illustrates an example system 500 in accordance with one or more implementations as described herein. In some cases, one or more aspects of system 300 may be fabricated by or in conjunction with system 200 of FIG. 2. In some configurations, one or more aspects of system 500 may be implemented by or in conjunction with machine 105, components of machine 105, or any combination thereof.

In the illustrated example, system 500 may include SA 505, which may be configured as a folded bitline sense amplifier. SA 505 may connect to one or more pairs of bitlines. For example, SA 505 may connect to a first pair of bitlines (e.g., BL 510 and BLB 515) and connect to a second pair of bitlines (e.g., BL 520, and BLB 525). In some cases, the bitlines of system 500 may cross paths with one or more wordlines. For example, WL 530 may pass adjacent to BL 510, and WL 535 may pass adjacent to BLB 515. Similarly, WL 540 may pass adjacent to BL 520, and WL 545 may pass adjacent to BLB 525. In some cases, the wordlines of system 500 may connect to one or more memory cells. For example, WL 530 may connect to memory cell 550, which may connect to BL 510. Similarly, WL 535 may connect to memory cell 555, which may connect to BLB 515; WL 540 may connect to memory cell 560, which may connect to BL 520; and WL 545 may connect to memory cell 565, which may connect to BLB 525.

In a sense amplifier (e.g., SA 505), the differential input voltage (the difference between BL and BLB) may be amplified to determine the data stored in a memory cell. As shown, SA 505 may include components (e.g., transistors, amplifiers 570 (e.g., differential amplifiers), etc.) to sense and amplify voltage differentials (e.g., delta VBL) between bitline pairs (e.g., between BL 510 and BLB 515, and/or between BL 520 and BLB 525). In some cases, SA 505 may measure delta VBL at 575 for BL 510 and BLB 515, and measure delta VBL at 580 for BL 520 and BLB 525.

Due to process variations and mismatches in a given amplifier's circuitry, there can be a voltage difference (e.g., offset voltage) between the input terminals, even when no input signal is present. This offset voltage can cause the amplifier to misinterpret a given signal, leading to incorrect readings or slower access times, particularly in low-power or deep sub-micrometer technologies. In some cases, the sense amplifier may be configured with circuitry (e.g., transistor switches) that provides offset canceling between the differential bitlines to reduce or eliminate an offset voltage between the input terminals of the sense amplifier (e.g., between BL and BLB). For example, SA 505 may include isolation transistors 585 and/or isolation transistors 590. By reducing or eliminating the offset voltage; (a) SA 505 is enabled to detect smaller voltage differences, leading to a wider sensing margin and more reliable data reading; (b) SA 505 can respond faster to the input signal, leading to faster access times in memory applications; and (c) the reduced offset voltage can allow for lower supply voltages, leading to lower power consumption.

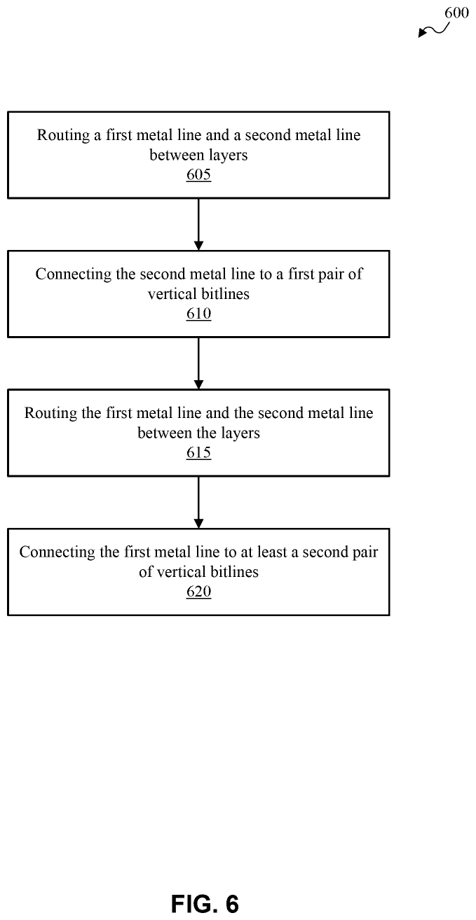

FIG. 6 depicts a flow diagram illustrating an example method 600 associated with the disclosed systems, in accordance with example implementations described herein. In some cases, one or more aspects of system 300 may be fabricated by or in conjunction with system 200 of FIG. 2. In some configurations, one or more aspects of method 600 may be implemented by or in conjunction with machine 105, components of machine 105, or any combination thereof. The depicted method 600 is just one implementation and one or more operations of method 600 may be rearranged, reordered, omitted, and/or otherwise modified such that other implementations are possible and contemplated.

At 605, method 600 may include routing a first metal line and a second metal line between layers. For example, method 600 may include routing, at a first location, a first metal line from a first routing layer to a second routing layer of a stacked memory module, and a second metal line from the second routing layer to the first routing layer.

At 610, method 600 may include connecting the second metal line to a first pair of vertical bitlines. For example, method 600 may include connecting, within a first span starting at the first location, the second metal line to at least a first pair of vertical bitlines of the stacked memory module. It is noted that routing may include directing a path of a metal line within a layer or between layers. Connecting may include forming a junction between two different items (e.g., forming a junction between a metal line and a bitline).

At 615, method 600 may include routing the first metal line and the second metal line between the layers. For example, method 600 may include routing, at a second location, the first metal line from the second routing layer to the first routing layer, and the second metal line from the first routing layer to the second routing layer.

At 620, method 600 may include connecting the first metal line to at least a second pair of vertical bitlines. For example, method 600 may include connecting, within a second span starting at the second location, the first metal line to at least a second pair of vertical bitlines of the stacked memory module.

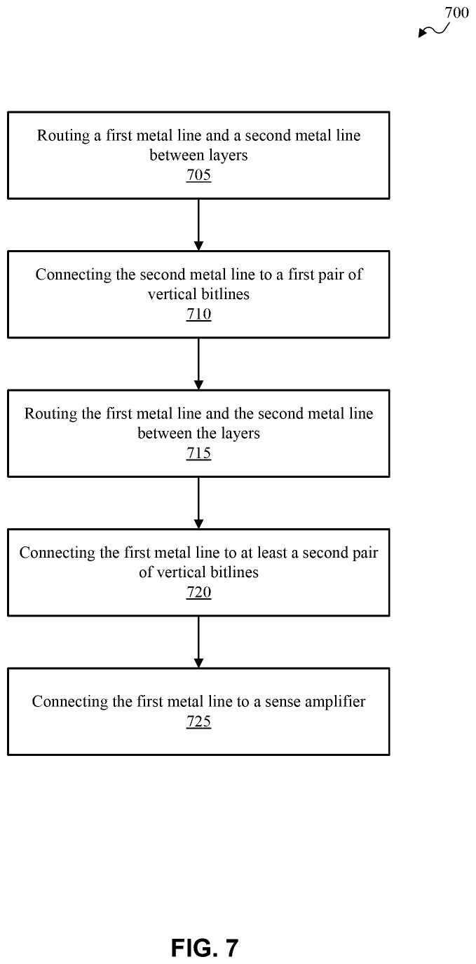

FIG. 7 depicts a flow diagram illustrating an example method 700 associated with the disclosed systems, in accordance with example implementations described herein. In some cases, one or more aspects of system 300 may be fabricated by or in conjunction with system 200 of FIG. 2. In some configurations, one or more aspects of method 700 may be implemented by or in conjunction with machine 105, components of machine 105, or any combination thereof. The depicted method 700 is just one implementation and one or more operations of method 700 may be rearranged, reordered, omitted, and/or otherwise modified such that other implementations are possible and contemplated.

At 705, method 700 may include routing a first metal line and a second metal line between layers. For example, method 700 may include routing, at a first location, a first metal line from a first routing layer to a second routing layer of a stacked memory module, and a second metal line from the second routing layer to the first routing layer.

At 710, method 700 may include connecting the second metal line to a first pair of vertical bitlines. For example, method 700 may include connecting, within a first span starting at the first location, the second metal line to at least a first pair of vertical bitlines of the stacked memory module.

At 715, method 700 may include routing the first metal line and the second metal line between the layers. For example, method 700 may include routing, at a second location, the first metal line from the second routing layer to the first routing layer, and the second metal line from the first routing layer to the second routing layer.

At 720, method 700 may include connecting the first metal line to at least a second pair of vertical bitlines. For example, method 700 may include connecting, within a second span starting at the second location, the first metal line to at least a second pair of vertical bitlines of the stacked memory module.

At 725, method 700 may include connecting the first metal line to a sense amplifier. For example, method 700 may include connecting the first metal line to a sense amplifier based on routing, within the first span or a first subsequent span, a first via from the first metal line to a sense amplifier. Additionally, or alternatively, method 700 may include connecting the second metal line to the sense amplifier based on routing, within the second span or a second subsequent span, a second via from the second metal line to the sense amplifier.

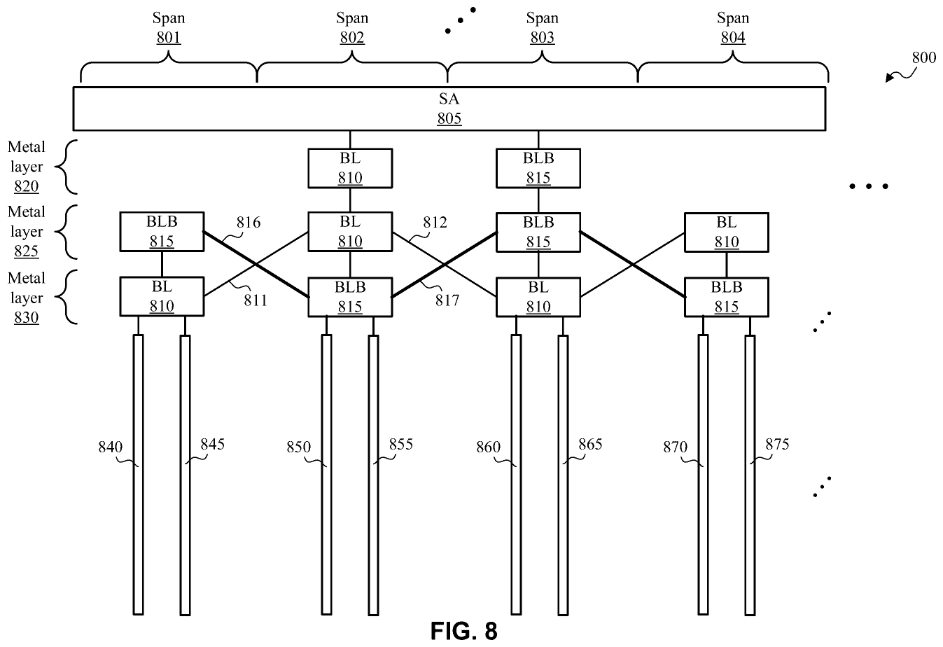

FIG. 8 illustrates an example system 800 in accordance with one or more implementations as described herein. In some cases, one or more aspects of system 300 may be fabricated by or in conjunction with system 200 of FIG. 2. In some configurations, one or more aspects of system 800 may be implemented by or in conjunction with machine 105, components of machine 105, or any combination thereof. FIG. 8 may depict a cross-section view of vertical twist global bitlines.

In the illustrated example, system 800 may include SA 805, bitline (BL) 810, and bitline bar (BLB) 815. In some cases, BL 810 may be referred to as a global bitline that connects to a first set of one or more local bitlines. Similarly, BLB 815 may be referred to as a global bitline bar that connects to a second set of one or more local bitlines. As shown, system 800 may include multiple memory cells (e.g., memory cells of the bank of SA 805) that connect to respective local bitlines of system 800.

In some configurations, SA 805 may be located above the depicted components of system 800 (e.g., above BL 810, BLB 815, memory cells, cross-section of wordlines, etc.). In some cases, system 800 may depict one bank of multiple banks. For example, system 800 may include multiple banks that include the bank of SA 805. In some cases, the multiple banks may continue into and/or from the page when viewing FIG. 8, where the components of system 800 are duplicated in a second bank, duplicated in a third bank, etc.

As shown, system 800 may include metal layer 820 under SA 805, metal layer 825 under metal layer 820, and metal layer 830 under metal layer 825. In some configurations, BL 810 may be routed from metal layer 825 to metal layer 830, and from metal layer 830 to metal layer 825. Similarly, BLB 815 may be routed from metal layer 825 to metal layer 830, and from metal layer 830 to metal layer 825. In the illustrated example, BLB 815 may be routed, via metal line 816, from metal layer 825 to metal layer 830. And BLB 815 may be routed, via metal line 817, from metal layer 830 to metal layer 825. In the illustrated example, BL 810 may be routed, via metal line 811, from metal layer 830 to metal layer 825. And BL 810 may be routed, via metal line 812, from metal layer 825 to metal layer 830.

System 800 may include multiple wordlines. A given memory cell may connect to a wordline. A given wordline may traverse into the page and/or out from the page from the perspective of the depicted view of FIG. 8. In some examples, the wordlines may connect to other banks of memory cells that connect to other vertical local bitlines, which connect to other SAs. For example, in addition to connecting to a memory cell in the depicted cross-section of FIG. 8, a given wordline may connect to a second memory cell of a second bank adjacent to the bank of SA 805 (e.g., a bank set into the depicted view or out from the depicted view of FIG. 8). Additionally, the wordline may connect to a third memory cell of a third bank adjacent to the second bank, and so on.

In some examples, BL 810 or BLB 815 may connect to two or more local bitlines. A shown, within a first span (e.g., span 801), BL 810 may be routed through metal layer 830, and BLB 815 may be routed over BL 810, through metal layer 825. Within span 801, BL 810 may connect to local bitline (LBL) 840 and LBL 845. As shown, LBL 840 and LBL 845 may be positioned vertically under metal layer 830. In some cases, LBL 840 may connect to a first portion of memory cells and LBL 845 may connect to a second portion of memory cells of system 800. For example, LBL 840 and/or LBL 845 may connect to one or more respective memory cells; LBL 850 and/or LBL 855 may connect to one or more respective memory cells; LBL 860 and/or LBL 865 may connect to one or more respective memory cells; LBL 870 and/or LBL 875 may connect to one or more respective memory cells; etc.

A first portion of memory cells may connect to a first portion of wordlines that run through system 800 on either side of LBL 840 (e.g., see MC 460, MC 465 of FIG. 4). In some examples, a first set of wordlines may run adjacent to and on a first side of LBL 840 and a second set of wordlines may run adjacent to and on a second side of LBL 840 (e.g., see WL 480, WL 485 of FIG. 4). Similarly, a third set of wordlines may run adjacent to and on a first side of LBL 845 and a fourth set of wordlines may run adjacent to and on a second side of LBL 845, and so on (e.g., see FIG. 4).

In some examples, to read a memory cell, a wordline connected to the memory cell may be activated (e.g., an active charge applied to the wordline). The voltage level of BL 810, connected to the memory cell and SA 805, may be affected based on activating the wordline. SA 805 may compare a voltage level of BL 810 to a voltage level of BLB 815, where the voltage level of BLB 815 may be a reference voltage for BL 810. SA 805 may detect a slight voltage difference (e.g., delta VBL) between BL 810 and BLB 815, which may indicate the value stored at the memory cell.

Between span 801 and a second span (e.g., span 802), BL 810 may be routed from metal layer 830 to metal layer 825, while BLB 815 may be routed from metal layer 825 to metal layer 830. Within span 802, BLB 815 may be routed through metal layer 830, and BL 810 may be routed over BLB 815, through metal layer 830. Within span 802, BLB 815 may connect to LBL 850 and LBL 855. As shown, LBL 850 and LBL 855 may be positioned vertically under metal layer 830. In some cases, LBL 850 may connect to a third portion of memory cells and LBL 855 may connect to a fourth portion of memory cells of system 800. The third portion of memory cells and fourth portion of memory cells may connect to respective wordlines that run through system 800 (e.g., in and out of the depicted view of FIG. 8) on either side of LBL 850 and LBL 855, respectively. For example, in span 802, a first set of wordlines may run adjacent to and on a first side of LBL 850 and a second set of wordlines may run adjacent to and on a second side of LBL 850. Similarly, a third set of wordlines may run adjacent to and on a first side of LBL 855 and a fourth set of wordlines may run adjacent to and on a second side of LBL 855.

Between the second span and a third span (e.g., span 803), BL 810 may be routed from metal layer 825 to metal layer 830, while BLB 815 may be routed from metal layer 830 to metal layer 825. Within span 803, BL 810 may be routed through metal layer 830, and BLB 815 may be routed over BL 810, through metal layer 825. Within span 803, BL 810 may connect to LBL 860 and LBL 865. As shown, LBL 860 and LBL 865 may be positioned vertically under metal layer 830. In some cases, LBL 860 may connect to a fifth portion of memory cells and LBL 865 may connect to a sixth portion of memory cells of system 800. The fifth portion of memory cells may connect to wordlines that run through system 800 on either side of LBL 860. Similarly, the sixth portion of memory cells may connect to wordlines that run through system 800 on either side of LBL 865.

Between span 803 and a fourth span (e.g., span 804), BL 810 may be routed from metal layer 830 to metal layer 825, while BLB 815 may be routed from metal layer 825 to metal layer 830. Within span 804, BL 810 may be routed through metal layer 830, and BLB 815 may be routed over BL 810, through metal layer 825. Within span 804, BL 810 may connect to LBL 870 and LBL 875. As shown, LBL 870 and LBL 875 may be positioned vertically under metal layer 830. In some cases, LBL 870 may connect to a seventh portion of memory cells and LBL 875 may connect to an eighth portion of memory cells of system 800. The seventh portion of memory cells and the eighth portion of memory cells may connect to respective wordlines that run through system 800 on either side of LBL 870 and either side of LBL 875.

As shown, SA 805 may connect to at least one pair of bitlines (e.g., BL 810 and BLB 815). In some cases, SA 805 may connect to two or more pairs of bitlines. For example, SA 805 may connect to a first bitline pair (e.g., BL 810 and BLB 815) as well as at least one additional bitline pair (e.g., a second BL and BLB pair). In some cases, the second pair of bitlines may include another BL connection to SA 805 and another BLB connection to SA 805. The second BL connection may connect to a first twisted bitline similar to BL 810, and the second BLB connection may connect to a second twisted bitline similar to BLB 815. The second BL may connect to a first set of one or more local bitlines, and the second BLB may connect to a second set of one or more local bitlines. The second BL may be electrically isolated (e.g., not connected) to BL 810 or BLB 815. Similarly, the second BLB may be electrically isolated (e.g., not connected) to BL 810 or BLB 815. In some cases, the depicted components of system 800 may be referred to as a first array (e.g., first memory cell array), and the components of the second BL and second BLB may be referred to as a second array (e.g., second memory cell array). Thus, one or more memory cell arrays may connect to SA 805.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wired and/or wireless communication device such as a switch, router, network interface controller, cellular telephone, smartphone, tablet, netbook, wireless terminal, laptop computer, a femtocell, High Data Rate (HDR) subscriber station, access point, printer, point of sale device, access terminal, or other personal communication system (PCS) device. The device may be wireless, wired, mobile, and/or stationary.

As used within this document, the term “communicate” is intended to include transmitting, or receiving, or both transmitting and receiving. Similarly, the bidirectional exchange of data between two devices (both devices transmit and receive during the exchange) may be described as ‘communicating’, when only the functionality of one of those devices is being claimed. The term “communicating” as used herein with respect to wired and/or wireless communication signals includes transmitting the wired and/or wireless communication signals and/or receiving the wired and/or wireless communication signals. For example, a communication unit, which is capable of communicating wired and/or wireless communication signals, may include a wired/wireless transmitter to transmit communication signals to at least one other communication unit, and/or a wired/wireless communication receiver to receive the communication signal from at least one other communication unit.

Some embodiments may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, a wired or wireless network, a wireless area network, a Wireless Video Area Network (WVAN), a Local Area Network (LAN), a Wireless LAN (WLAN), a Personal Area Network (PAN), a Wireless PAN (WPAN), and the like.

Some embodiments may be used in conjunction with one way and/or two-way radio communication systems, cellular radio-telephone communication systems, a mobile phone, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example, a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random-access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples as set forth herein will come to mind to one skilled in the art to which these embodiments pertain to having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A method comprising:
routing, at a first location, a first metal line from a first routing layer to a second routing layer of a stacked memory module, and a second metal line from the second routing layer to the first routing layer;
connecting, within a first span starting at the first location, the second metal line to at least a first pair of vertical bitlines of the stacked memory module;
routing, at a second location, the first metal line from the second routing layer to the first routing layer, and the second metal line from the first routing layer to the second routing layer; and
connecting, within a second span starting at the second location, the first metal line to at least a second pair of vertical bitlines of the stacked memory module.

2. The method of claim 1, further comprising:
connecting the first metal line to a sense amplifier of the stacked memory module based on routing, within the first span or a first subsequent span, a first via from the first metal line to the sense amplifier; and
connecting the second metal line to the sense amplifier based on routing, within the second span or a second subsequent span, a second via from the second metal line to the sense amplifier.

3. The method of claim 2, wherein:
a wordline of the stacked memory module shares a charge with the second via when the wordline is activated, and
the first via is isolated from the charge of the wordline when the wordline is activated.

4. The method of claim 2, wherein:
a wordline of the stacked memory module runs orthogonal to the first pair of vertical bitlines and the second pair of vertical bitlines, and
the wordline runs orthogonal to the first metal line and the second metal line.

5. The method of claim 2, wherein:
the stacked memory module includes multiple banks of vertical bitlines, and
a first bank of the multiple banks includes the first pair of vertical bitlines, the second pair of vertical bitlines, the first routing layer, the second routing layer, the first via, the second via, and the sense amplifier.

6. The method of claim 5, wherein a second bank of the multiple banks runs parallel to the first bank and includes:
a third pair of vertical bitlines connected to a third routing layer,
a fourth pair of vertical bitlines connected to a fourth routing layer,
a third via connecting the third routing layer to a second sense amplifier, and
a fourth via connecting the fourth routing layer to the second sense amplifier.

7. The method of claim 1, wherein:
a first set of wordlines are routed adjacent to a first bitline of the first pair of vertical bitlines, and connect, respectively, to a first set of memory cells connected to the first bitline, and
a second set of wordlines are routed adjacent to the first bitline, and connect, respectively, to a second set of memory cells connected to the first bitline.

8. The method of claim 1, wherein:
the first metal line is connected to M vertical bitlines, M being a positive integer and a multiple of two, the M vertical bitlines including the second pair of vertical bitlines, and
the second metal line is connected to N vertical bitlines, N being a positive integer and a multiple of two, the N vertical bitlines including the first pair of vertical bitlines, N being greater than, less than, or equal to M.

9. The method of claim 1, wherein the first pair of vertical bitlines and the second pair of vertical bitlines run orthogonal to the first metal line and the second metal line.

10. The method of claim 1, wherein the first routing layer is beneath the second routing layer in the stacked memory module.

11. A stacked memory module comprising:
a first metal line routed, at a first location, from a first routing layer to a second routing layer of the stacked memory module,
a second metal line routed, at the first location, from the second routing layer to the first routing layer;
a first pair of vertical bitlines of the stacked memory module connected, within a first span starting at the first location, to the second metal line;
the first metal line routed, at a second location, from the second routing layer to the first routing layer, and the second metal line routed, at the second location, from the first routing layer to the second routing layer; and
a second pair of vertical bitlines of the stacked memory module connected, within a second span starting at the second location, to the first metal line.

12. The stacked memory module of claim 11, wherein the stacked memory module further comprises:
a sense amplifier connected to the first metal line based on a first via that is routed, within the first span or a first subsequent span, from the first metal line to the sense amplifier; and
the second metal line connected to the sense amplifier based on a second via that is routed, within the second span or a second subsequent span, from the second metal line to the sense amplifier.

13. The stacked memory module of claim 12, wherein the stacked memory module is configured to read a value stored in a memory cell connected to the first via, wherein reading the value is based on:
the stacked memory module activating a wordline of the memory cell, and
the sense amplifier detecting a voltage differential between the first via and the second via.

14. The stacked memory module of claim 12, wherein:
the stacked memory module comprises a wordline that shares a charge with the second via when the wordline is activated, and
the first via is isolated from the charge of the wordline when the wordline is activated.

15. The stacked memory module of claim 12, wherein:
the stacked memory module comprises a wordline that runs orthogonal to the first pair of vertical bitlines and the second pair of vertical bitlines, and
the wordline runs orthogonal to the first metal line and the second metal line.

16. The stacked memory module of claim 12, wherein:
the stacked memory module includes multiple banks of vertical bitlines, and
a first bank of the multiple banks includes the first pair of vertical bitlines, the second pair of vertical bitlines, the first routing layer, the second routing layer, the first via, the second via, and the sense amplifier.

17. The stacked memory module of claim 11, wherein:
a first set of wordlines are routed adjacent to a first bitline of the first pair of vertical bitlines, and connect, respectively, to a first set of memory cells connected to the first bitline, and
a second set of wordlines are routed adjacent to the first bitline, and connect, respectively, to a second set of memory cells connected to the first bitline.

18. A fabrication system comprising:
a routing controller to:
route, at a first location, a first metal line from a first routing layer to a second routing layer of a stacked memory module, and a second metal line from the second routing layer to the first routing layer;
connect, within a first span starting at the first location, the second metal line to at least a first pair of vertical bitlines of the stacked memory module;
route, at a second location, the first metal line from the second routing layer to the first routing layer, and the second metal line from the first routing layer to the second routing layer; and
connect, within a second span starting at the second location, the first metal line to at least a second pair of vertical bitlines of the stacked memory module.

19. The fabrication system of claim 18, wherein the fabrication system is further configured to:
connect the first metal line to a sense amplifier of the stacked memory module based on the routing controller routing, within the first span or a first subsequent span, a first via from the first metal line to the sense amplifier; and
connect the second metal line to the sense amplifier based on the routing controller routing, within the second span or a second subsequent span, a second via from the second metal line to the sense amplifier.

20. The fabrication system of claim 19, wherein:
the fabrication system configures a wordline of the stacked memory module to share a charge with the second via when the wordline is activated, and
the first via is isolated from the charge of the wordline when the wordline is activated.
